(19) United States
(12) Patent Application Publication
(10) Pub. No.: US 2021/0249628 A1
(43) Pub. Date: Aug. 12, 2021

(54) FLEXIBLE DISPLAY PANEL, DISPLAY DEVICE, AND DISPLAY DEVICE MANUFACTURING METHOD

(71) Applicant: Wuhan China Star Optoelectronics Semiconductor Display Technology Co., Ltd., Wuhan, Hubei (CN)

(72) Inventors: Chunmei HE, Wuhan, Hubei (CN); Haochun LEE, Wuhan, Hubei (CN)

(21) Appl. No.: 16/759,341

(22) PCT Filed: Mar. 13, 2020
(86) PCT No.: PCT/CN2020/079158

§ 371 Date: Apr. 26, 2020

(30) Foreign Application Priority Data
Feb. 10, 2020 (CN) 202010083864.X

(51) Int. Cl. H01L 51/52; H01L 51/56

(52) U.S. Cl. CPC H01L 51/5253; H01L 51/56; H01L 2251/308; H01L 2251/5338; H01L 51/5293

(57) ABSTRACT

The present invention provides a flexible display panel, a display device, and a display device manufacturing method. the flexible display panel includes a backplate, drive circuit layer, a light emitting function layer, and an encapsulation layer. The backplate is a super thin tempered glass thin film, a thickness of the tempered glass thin film is less than 70 microns. The present invention by employing the super thin tempered glass as the backplate mitigates the issue of creases in a folding region of a folding product.

### FIELD OF INVENTION

The present invention relates to a field of display technologies, especially relates to a flexible display panel, display device and a display device manufacturing method.

### BACKGROUND OF INVENTION

With the birth of flexible substrate organic light emitting diode (OLED), demands of the market on display industries manufacturing flexible displays become high. Several manufacturers constantly set forth products such as folding phones or folding tablets. Flexible OLED folding products are highly demanding with backplates, and require the backplates to have a capability of repeatedly folding resistance. Therefore, the conventional backplate basically uses organic polymer materials such as poly ethylene terephthalate (PET) and polyimide (PI). However, molecular chains of such organic polymer materials are stretched during repeated folding, bond lengths and bond angles in the molecular chains is changed, and relative shifts occur among the molecules. When folding is stopped, in other words, the external force is released, some of deformation cannot be restored and causes creases. Furthermore, a module sample of folding products is not bonded to the entire machine in a folding region, and a gap therebetween easily receives a foreign matter. Because the module sample is thin and soft, the entering foreign matter of hard particles easily presses against and damages the display panel during folding.

Therefore, the backplate of the conventional flexible display panel has an issue of creases to be solved.

### SUMMARY OF INVENTION

The present invention provides a flexible display panel, a display device and a display device manufacturing method to mitigate the technical issue of the backplate of the conventional flexible display panel having creases.

To solve the above issue, the present invention provides technical solutions as follows:

The embodiment of the present invention provides a flexible display panel comprising a backplate; a drive circuit layer disposed on the backplate; a light emitting function layer disposed on the drive circuit layer; and an encapsulation layer disposed on the light emitting function layer; wherein the backplate is a glass thin film.

In the flexible display panel provided by the embodiment of the present invention, the glass thin film comprises a tempered glass thin film.

In the flexible display panel provided by the embodiment of the present invention, a thickness of the tempered glass thin film is less than 70 microns.

In the flexible display panel provided by the embodiment of the present invention, the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

In the flexible display panel provided by the embodiment of the present invention, a material of each of the buffer layer, the gate electrode insulation layer, the interlayer insulation layer, and the planarization layer comprises at least on of silicon oxide, nitride oxide, and nitride oxide.

In the flexible display panel provided by the embodiment of the present invention, a material of the pixel electrode comprises indium tin oxide.

The embodiment of the present invention provides a display device, comprising a flexible display panel, a polarizer disposed on the flexible display panel, and a cover lid, wherein the flexible display panel comprises: a backplate;

a drive circuit layer disposed on the backplate; a light emitting function layer disposed on the drive circuit layer; and an encapsulation layer disposed on the light emitting function layer; wherein the backplate is a glass thin film.

In the display device provided by the embodiment of the present invention, the glass thin film comprises a tempered glass thin film.

In the display device provided by the embodiment of the present invention, a thickness of the tempered glass thin film is less than 70 microns.

In the display device provided by the embodiment of the present invention, the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

In the display device provided by the embodiment of the present invention, a material of each of the buffer layer, the gate electrode insulation layer, the interlayer insulation layer, and the planarization layer comprises at least one of silicon oxide, nitride oxide, and nitride oxide

In the display device provided by the embodiment of the present invention, a material of the pixel electrode comprises indium tin oxide.

The embodiment of the present invention also provides a display device manufacturing method, comprising: a step S10, manufacturing a backplate, and comprising providing a glass substrate and attaching a glass thin film on the glass substrate as the backplate; a step S20, manufacturing a drive circuit layer, and comprising manufacturing the drive circuit layer on the backplate; a step S30, manufacturing a light emitting function layer, and comprising manufacturing the light emitting function layer on the drive circuit layer; a step S40, manufacturing an encapsulation layer, and comprising manufacturing the encapsulation layer on the light emitting function layer; a step S50, attaching a polarizer, and comprising attaching a protective film on the encapsulation layer and attaching the polarizer on the protective film; a step S60, attaching a cover lid, and comprising attaching the cover lid on the polarizer; and a step S70, releasing the glass substrate.

In the display device manufacturing method provided by the embodiment of the present invention, in the step S10, a thickness of the tempered glass thin film is less than 70 microns.

In the display device manufacturing method provided by the embodiment of the present invention, a thickness of the tempered glass thin film is less than 70 microns.

In the display device manufacturing method provided by the embodiment of the present invention, in the step S10, an adhesive configured for attaching the glass thin film is an ultra violet release adhesive.

In the display device manufacturing method provided by the embodiment of the present invention, in the step S20, the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

In the display device manufacturing method provided by the embodiment of the present invention, in the step S50, an adhesive configured for attaching the polarizer is an optical clear adhesive (OCA).

In the display device manufacturing method provided by the embodiment of the present invention, in the step S60, the cover lid is a cover window.

In the display device manufacturing method provided by the embodiment of the present invention, the step S70 comprises irradiating the display device by ultra violet to lower a viscosity of the ultra violet release adhesive such that the glass substrate is released from the backplate.

Advantages of the present invention are as follows: In the flexible display panel, the display device, and the display device manufacturing method provided by the present invention, use a super thin tempered glass thin film with a thickness less than 70 microns to replace a traditional organic polymer material as a backplate. The modulus of the super thin tempered glass thin film is high so the super thin tempered glass thin film has less deformation when receiving an external force and can restore to its original shape after the external force is released, which effectively solves the issue of creases on the backplate in the conventional flexible display panel. Furthermore, using the super thin tempered glass thin film as a backplate mitigates unevenness of appearance of the module and lowers a probability of a foreign matter of hard particles entering a gap of a folding region and damaging the display panel.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic side view of a flexible display panel provided by an embodiment of the present invention.

FIG. 2 is a schematic side view of a display device provided by the embodiment of the present invention.

FIG. 3 is a schematic side view of a drive circuit layer provided by the embodiment of the present invention.

FIG. 4 is a flowchart of a display device manufacturing method provided by the embodiment of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

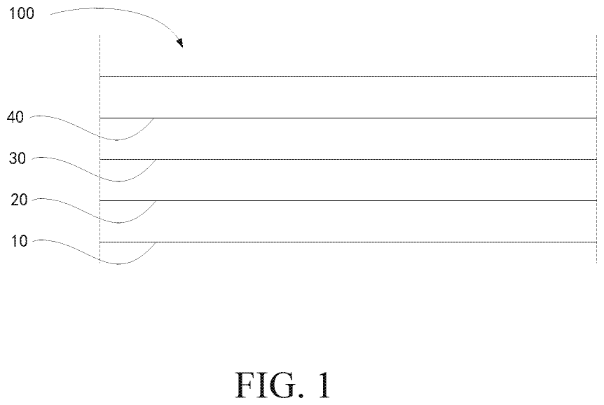

In an embodiment, with reference to FIG. 1, a flexible display panel 100 is provided and comprises a backplate 10, a drive circuit layer 20, a light emitting function layer 30, and an encapsulation layer 40. The drive circuit layer 20 is disposed on the backplate 10. the light emitting function layer 30 is disposed on the drive circuit layer 20. the encapsulation layer 40 is disposed on the light emitting function layer 30. The backplate 10 is a glass thin film.

Specifically, the glass thin film comprises a tempered glass thin film.

Furthermore, a thickness of the tempered glass thin film is less than 70 microns.

In the present embodiment, a super thin tempered glass thin film serves as the backplate, a modulus of the super thin tempered glass thin film is high so the super thin tempered glass thin film has less deformation when receiving an external force and can restore to its original shape after the external force is released, which effectively solves the issue of creases on the backplate in the conventional flexible display panel.

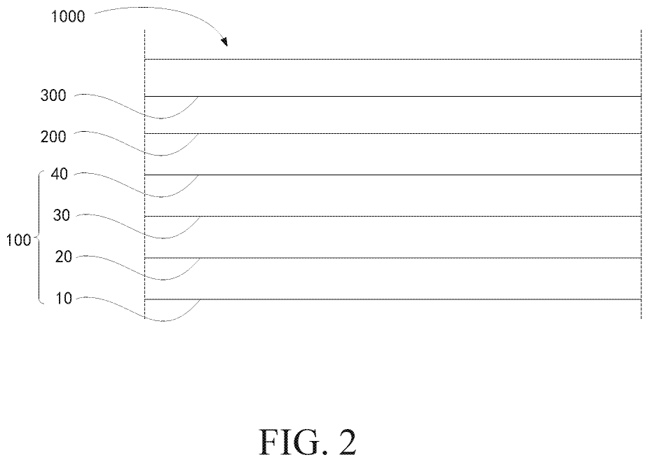

In an embodiment, with reference to FIG. 2, a display device 1000 is provided and comprises a flexible display panel 100, and a polarizer 200 and a cover lid 300 disposed on the flexible display panel 100.

Specifically, the flexible display panel 100 comprises a backplate 10, a drive circuit layer 20, a light emitting function layer 30, and an encapsulation layer 40 that are stacked on one another. The backplate 10 is a tempered glass thin film, and a thickness of the tempered glass thin film is less than 70 microns.

Specifically, in tradition, an ultra violet (UV) release adhesive is covered on the glass substrate by a coating process, and then the super thin tempered glass thin film is attached thereon. When irradiated by ultra violet, a viscosity of the ultra violet release adhesive decreases. The super thin tempered glass thin film can be manufactured by reducing a thickness of a general tempered glass to be less than 70 microns.

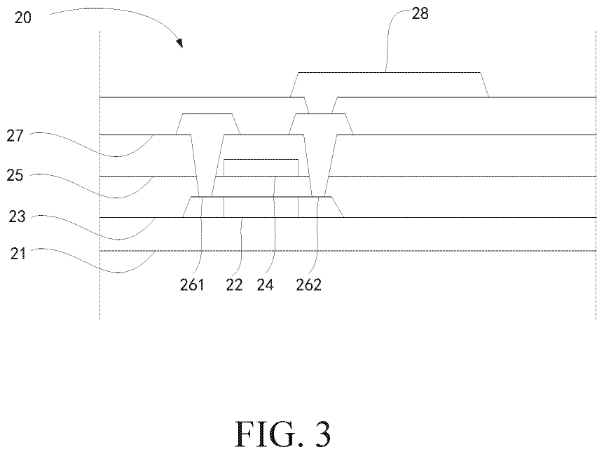

Furthermore, the drive circuit layer is directly manufactured on the super thin tempered glass thin film. With reference to FIG. 3, the drive circuit layer 20 comprises a buffer layer 21, an active layer 22, a gate electrode insulation layer 23, a gate electrode 24, an interlayer insulation layer 25, a source electrode 261, a drain electrode 262, a planarization layer 27, and a pixel electrode 28.

Specifically, with reference to FIG. 3, the source electrode 261 and the drain electrode 262 are connected to a doping region of the active layer 22 through via holes. The pixel electrode 28 is connected to the drain electrode 262 through via holes.

Furthermore, the light emitting function layer is manufactured on the drive circuit layer, and the light emitting function layer comprises a pixel definition layer, a light emitting layer, and a cathode layer.

Furthermore, the encapsulation layer is manufactured on the light emitting function layer, and the encapsulation layer can employ a thin film encapsulation comprising a first inorganic encapsulation layer, an organic encapsulation layer, and a second inorganic encapsulation layer.

Furthermore, a protective film is manufactured on the encapsulation layer.

Furthermore, an optical clear adhesive (OCA) is coated on the protective film, and the polarizer is attached on the protective film with the OCA.

Furthermore, the OCA is coated on the polarizer, and the cover lid is attached on the polarizer with the OCA. The cover lid can be a cover window (CW).

Furthermore, the display device completing the above module process is processed with ultra violet irradiation. When receiving ultra violet irradiated, the ultra violet release adhesive has a lowered viscosity, the glass substrate can be stripped off such that the glass substrate separates from the super thin tempered glass thin film.

Specifically, a modulus of the super thin tempered glass thin film is about 10 times greater than a modulus of polyimide or polyethylene terephthalate. When receiving an external force, the super thin tempered glass thin film has less deformation and can restore its original shape after the external force is released without creases left thereon. A module structure of a folding screen is formed from multiple stacked thin films. During folding, a strain of each thin film is continuous, addition of glass lowers the strain of other film layer such that the crease phenomenon cab be effectively eliminated. Furthermore, using the super thin tempered glass thin film as the backplate can also mitigate unevenness of appearance of the module while lower a probability of a foreign matter of hard particles pressing against and damaging the display panel after entering the gap of the folding region.

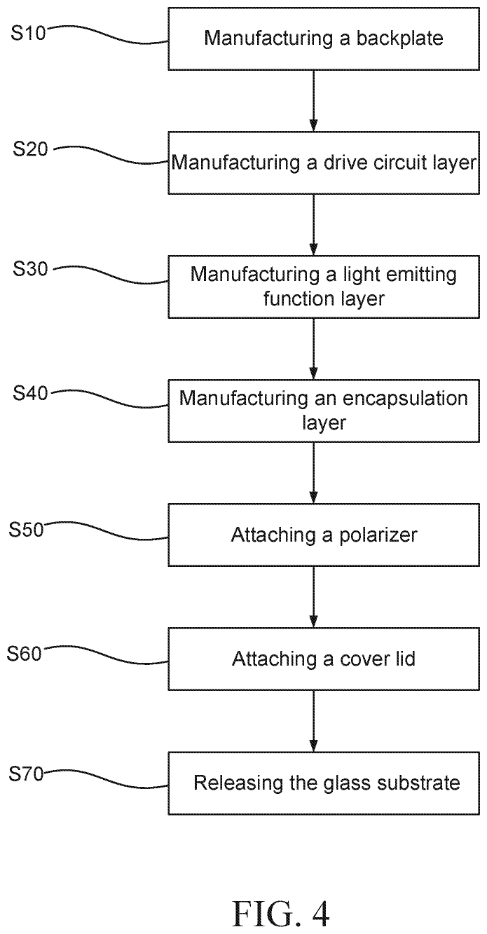

In an embodiment, a display device manufacturing method is provided as shown in FIG. 4 and comprises steps S10 to 70.

The step S10 comprises manufacturing a backplate, and further comprises providing a glass substrate and attaching a glass thin film on the glass substrate as the backplate.

Specifically, a ultra violet release adhesive is coated on the glass substrate by a coating process, and then a glass thin film is attached on the glass substrate coated with the ultra violet release adhesive. The glass thin film is a super thin tempered glass thin film, and the super thin tempered glass thin film is generally made by reducing a thickness of a general tempered glass to be less than 70 microns.

The step S20 comprises manufacturing a drive circuit layer, and further comprises manufacturing the drive circuit layer on the backplate.

Specifically, the drive circuit layer comprises a buffer layer, an active layer, a gate electrode insulation layer, a gate electrode, an interlayer insulation layer, a source electrode, a drain electrode, a planarization layer, and a pixel electrode.

Furthermore, a material of each the buffer layer, the gate electrode insulation layer, the interlayer insulation layer, and the planarization layer comprises an inorganic material such as silicon oxide (SiOx), nitride oxide (SiNx), nitride oxide (SiNO) or a combination thereof.

Furthermore, a material of the pixel electrode comprises a transparent electrode material such as indium tin oxide (ITO).

The step S30 comprises manufacturing a light emitting function layer, and further comprises manufacturing the light emitting function layer on the drive circuit layer.

Specifically, the light emitting function layer comprises a pixel definition layer, a light emitting layer, and a cathode layer.

The step S40 comprises manufacturing an encapsulation layer, and further comprises manufacturing the encapsulation layer on the light emitting function layer.

Specifically, the encapsulation layer can employ a thin film encapsulation, and comprises a first inorganic encapsulation layer, an organic encapsulation layer, and a second inorganic encapsulation layer. The first inorganic encapsulation layer and the second inorganic encapsulation layer can be manufactured by a physical vapor deposition (PVD) process, a chemical vapor deposition (CVD) process, or an atomic layer deposition (ALD) process deposition process. The organic encapsulation layer can be manufactured by an ink jet print (IJP) process.

The step S50 comprises attaching aa polarizer, and further comprises attaching a protective film on the encapsulation layer and attaching the polarizer the protective film.

Specifically, the OCA is coated on the protective film, and then the polarizer is coated on the protective film with the OCA.

The step S60 comprises attaching a cover lid, and further comprises attaching the cover lid on the polarizer.

Specifically, the OCA is coated on the polarizer, and then the cover lid is attached on the polarizer with the OCA. The cover lid can be a cover window.

The step S70 comprises releasing the glass substrate.

Specifically, after the cover lid is attached, ultra violet irradiation is implemented to the display device. When receiving ultra violet irradiation, the ultra violet release adhesive has a lowered viscosity the glass substrate can be stripped off such that the glass substrate separates from the super thin tempered glass thin film.

It is concluded as follows according to the above embodiments:

The present invention provides a flexible display panel, a display device and a display device manufacturing method. The flexible display panel comprises a backplate, a drive circuit layer, a light emitting function layer, and an encapsulation layer. The backplate is a super thin tempered glass thin film, and a thickness of the tempered glass thin film is less than 70 microns. A modulus of the super thin tempered glass thin film is about 10 times greater than a modulus of polyimide or polyethylene terephthalate. When receiving an external force, the super thin tempered glass thin film has less deformation and can restore its original shape after the external force is released without creases left thereon. A module structure of a folding screen is formed from multiple stacked thin films. During folding, a strain of each thin film is continuous, addition of glass lowers the strain of other film layer such that the crease phenomenon cab be effectively eliminated. Furthermore, using the super thin tempered glass thin film as the backplate can also mitigate unevenness of appearance of the module while lower a probability of a foreign matter of hard particles pressing against and damaging the display panel after entering the gap of the folding region.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A flexible display panel, comprising:
a backplate;
a drive circuit layer disposed on the backplate;
a light emitting function layer disposed on the drive circuit layer; and
an encapsulation layer disposed on the light emitting function layer;
wherein the backplate is a glass thin film.

2. The flexible display panel as claimed in claim 1, wherein the glass thin film comprises a tempered glass thin film.

3. The flexible display panel as claimed in claim 2, wherein a thickness of the tempered glass thin film is less than 70 microns.

4. The flexible display panel as claimed in claim 1, wherein the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

5. The flexible display panel as claimed in claim 4, wherein a material of each of the buffer layer, the gate electrode insulation layer, the interlayer insulation layer, and the planarization layer comprises at least on of silicon oxide, nitride oxide, and nitride oxide.

6. The flexible display panel as claimed in claim 4, wherein a material of the pixel electrode comprises indium tin oxide.

7. A display device, comprising a flexible display panel, a polarizer disposed on the flexible display panel, and a cover lid, wherein the flexible display panel comprises:
a backplate;
a drive circuit layer disposed on the backplate;
a light emitting function layer disposed on the drive circuit layer; and
an encapsulation layer disposed on the light emitting function layer;
wherein the backplate is a glass thin film.

8. The display device as claimed in claim 7, wherein the glass thin film comprises a tempered glass thin film.

9. The display device as claimed in claim 8, wherein a thickness of the tempered glass thin film is less than 70 microns.

10. The display device as claimed in claim 7, wherein the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

11. The display device as claimed in claim 10, wherein a material of each of the buffer layer, the gate electrode insulation layer, the interlayer insulation layer, and the planarization layer comprises at least one of silicon oxide, nitride oxide, and nitride oxide.

12. The display device as claimed in claim 10, wherein a material of the pixel electrode comprises indium tin oxide.

13. A display device manufacturing method, comprising:
a step S10, manufacturing a backplate, and comprising providing a glass substrate and attaching a glass thin film on the glass substrate as the backplate;
a step S20, manufacturing a drive circuit layer, and comprising manufacturing the drive circuit layer on the backplate;
a step S30, manufacturing a light emitting function layer, and comprising manufacturing the light emitting function layer on the drive circuit layer;
a step S40, manufacturing an encapsulation layer, and comprising manufacturing the encapsulation layer on the light emitting function layer;
a step S50, attaching a polarizer, and comprising attaching a protective film on the encapsulation layer and attaching the polarizer on the protective film;
a step S60, attaching a cover lid, and comprising attaching the cover lid on the polarizer; and
a step S70, releasing the glass substrate.

14. The display device manufacturing method as claimed in claim 13, wherein in the step S10, the glass thin film is a tempered glass thin film.

15. The display device manufacturing method as claimed in claim 14, wherein a thickness of the tempered glass thin film is less than 70 microns.

16. The display device manufacturing method as claimed in claim 13, wherein in the step S10, an adhesive configured for attaching the glass thin film is an ultra violet release adhesive.

17. The display device manufacturing method as claimed in claim 13, wherein in the step S20, the drive circuit layer comprises a buffer layer, an active layer, a gate electrode insulation layer, a gate electrode, an interlayer insulation layer, a source electrode, a drain electrode, a planarization layer, and a pixel electrode that are stacked on one another.

18. The display device manufacturing method as claimed in claim 13, wherein in the step S50, an adhesive configured for attaching the polarizer is an optical clear adhesive (OCA).

19. The display device manufacturing method as claimed in claim 13, wherein in the step S60, the cover lid is a cover window.

20. The display device manufacturing method as claimed in claim 13, wherein the step S70 comprises irradiating the display device by ultra violet to lower a viscosity of the ultra violet release adhesive such that the glass substrate is released from the backplate.
